(19) United States
(12) Patent Application Publication
(10) Pub. No.: US 2017/0219349 A1
(43) Pub. Date: Aug. 3, 2017

(54) ANGULAR VELOCITY SENSOR ELEMENT

(71) Applicant: Panasonic Intellectual Property Management Co., Ltd., Osaka-shi, Osaka (JP)

(72) Inventor: Yasunobu KOBAYASHI, Fukui (JP)

(21) Appl. No.: 15/501,560

(22) PCT Filed: Aug. 25, 2015
(86) PCT No.: PCT/JP2015/004247

§ 371 Date: Feb. 3, 2017

(30) Foreign Application Priority Data
Sep. 1, 2014 (JP) 2014-176829

(51) Int. Cl. G01C 19/5607; H01L 41/113

(52) U.S. Cl. CPC G01C 19/5607; H01L 41/1132

(57) ABSTRACT

A disclosed angular velocity sensor element includes: a fixed part; a first detecting body connected to the fixed part, provided with a first detecting electrode, and extending in a first direction; a second detecting body connected at one end to the first detecting body, extending in a second direction approximately perpendicular to the first direction, and provided with a second detecting electrode; and a driving body connected to the other end of the second detecting body, disposed on a plane on which the first detecting body and the second detecting body are disposed, and provided with a driving electrode. The driving body has a folded shape with two or more bent portions such that a direction from a connecting portion of the second detecting body and the driving body to an end of the driving body is between the first direction and the second direction in a top view.

### TECHNICAL FIELD

The present disclosure relates to an angular velocity sensor element used for an angular velocity sensor, which is used in various kinds of electronic device.

### BACKGROUND ART

A conventional angular velocity sensor element will hereinafter be described with reference to the drawings.

FIG. 8 is a top view of a conventional angular velocity sensor element.

Each of fixed part 11, fixed part 13, detecting body 12, detecting body 14 and detecting body 15 is made of silicon (hereinafter referred to as Si). One end of detecting body 12 is connected to fixed part 11, and the other end of detecting body 12 is connected to fixed part 13. A detecting electrode (not shown) is provided on an upper surface of detecting body 12.

One end of detecting body 14 is connected to approximately a center of detecting body 12. Detecting body 14 is extending in a direction (the lateral direction in FIG. 8) approximately perpendicular to an extending direction of detecting body 12 (the vertical direction in FIG. 8). A detecting electrode (not shown) is provided on an upper surface of detecting body 14.

One end of detecting body 15 is connected to approximately a center of detecting body 12. Detecting body 15 is extending in a direction (the lateral direction in FIG. 8) approximately perpendicular to an extending direction of detecting body 12 (the vertical direction in FIG. 8). The extending direction of detecting body 15 is opposite to the extending direction of detecting body 14 from detecting body 12. Detecting body 14 and detecting body 15 are disposed to align in a straight line. A detecting electrode (not shown) is provided on an upper surface of detecting body 15.

Driving body 16 is extending as a whole from the other end of detecting body 14 in an oblique direction of +45 degrees, which is a direction between the extending direction of detecting body 12 and the extending direction of detecting body 14. A driving electrode (not shown) is provided on an upper surface of driving body 16.

Driving body 17 is extending as a whole from the other end of detecting body 14 in an oblique direction of −45 degrees, which is a direction between the extending direction of detecting body 12 and the extending direction of detecting body 14. A driving electrode (not shown) is provided on an upper surface of driving body 17.

Driving body 18 is extending as a whole from the other end of detecting body 15 in an oblique direction of −45 degrees, which is a direction between the extending direction of detecting body 12 and the extending direction of detecting body 15. A driving electrode (not shown) is provided on an upper surface of driving body 18.

Driving body 19 is extending as a whole from the other end of detecting body 15 in an oblique direction of +45 degrees, which is a direction between the extending direction of detecting body 12 and the extending direction of detecting body 15. A driving electrode (not shown) is provided on an upper surface of driving body 19.

Next, operations of the conventional angular velocity sensor element configured as above will be described.

Here, such a case will be considered that an angular velocity around the Y-axis direction is generated on the angular velocity sensor element.

Application of an AC voltage to the driving electrode (not shown) provided on the upper surface of each of driving body 16, driving body 17, driving body 18 and driving body 19 causes a driving oscillation of each of driving body 16, driving body 17, driving body 18 and driving body 19 at velocity V in the X-axis direction. In this condition, each of driving body 16, driving body 17, driving body 18 and driving body 19 oscillates around the Y-axis due to the Coriolis force.

These oscillations cause detecting body 14 and detecting body 15 to twist, so that detecting body 12 bends on the side of fixed part 11 and on the side of fixed part 13 in opposite directions to each other.

As a result, an electric charge corresponding to the angular velocity is generated at the detecting electrode (not shown) provided on the upper surface of detecting body 12. The electric charge is amplified through a circuit pattern (not shown) to be detected as the angular velocity around the Y-axis.

A known prior art reference related to the present application is, for example, PTL 1.

### CITATION LIST

### Patent Literature

PTL 1: International Patent Publication No. 2007/086337

### SUMMARY OF THE INVENTION

An angular velocity sensor element of the present disclosure has a configuration as described below.

An angular velocity sensor element of the present disclosure includes: a fixed part; a first detecting body connected to the fixed part and extending in a first direction, the first detecting body being provided with a first detecting electrode; a second detecting body connected at one end to the first detecting body and extending in a second direction approximately perpendicular to the first direction, the second detecting body being provided with a second detecting electrode; and a driving body connected to the other end of the second detecting body and disposed on a plane on which the first detecting body and the second detecting body are disposed, the driving body being provided with a driving electrode. The driving body has a folded shape with two or more bent portions such that a direction from a connecting portion of the second detecting body and the driving body to an end of the driving body is between the first direction and the second direction in a top view.

### BRIEF DESCRIPTION OF DRAWINGS

FIG. 1A is a top view of an angular velocity sensor element in accordance with an exemplary embodiment.

FIG. 1B is a top view of the angular velocity sensor element in accordance with the exemplary embodiment.

FIG. 2 is a side sectional view of a driving electrode of the angular velocity sensor element in accordance with the exemplary embodiment.

FIG. 3 is a schematic diagram illustrating a state of performing an oscillation analysis of a driving body and a weight part of the angular velocity sensor element in accordance with the exemplary embodiment by Finite Element Analysis (FEA).

FIG. 4A is an assembly process diagram of the angular velocity sensor element in accordance with the exemplary embodiment.

FIG. 4B is an assembly process diagram of the angular velocity sensor element in accordance with the exemplary embodiment.

FIG. 4C is an assembly process diagram of the angular velocity sensor element in accordance with the exemplary embodiment.

FIG. 4D is an assembly process diagram of the angular velocity sensor element in accordance with the exemplary embodiment.

FIG. 4E is an assembly process diagram of the angular velocity sensor element in accordance with the exemplary embodiment.

FIG. 5 is a diagram illustrating a state in which the angular velocity sensor element in accordance with the exemplary embodiment causes driving oscillations in the X-axis direction and the Y-axis direction.

FIG. 6 is a diagram illustrating an operating state in a case where an angular velocity around the X-axis is generated on the angular velocity sensor element in accordance with the exemplary embodiment.

FIG. 7 is a diagram illustrating an operating state in a case where an angular velocity around the Y-axis is generated on the angular velocity sensor element in accordance with the exemplary embodiment.

FIG. 8 is a top view of a conventional angular velocity sensor element.

### DESCRIPTION OF EMBODIMENT

Before describing the present exemplary embodiment, a problem of the conventional angular velocity sensor element the inventor(s) found will be described.

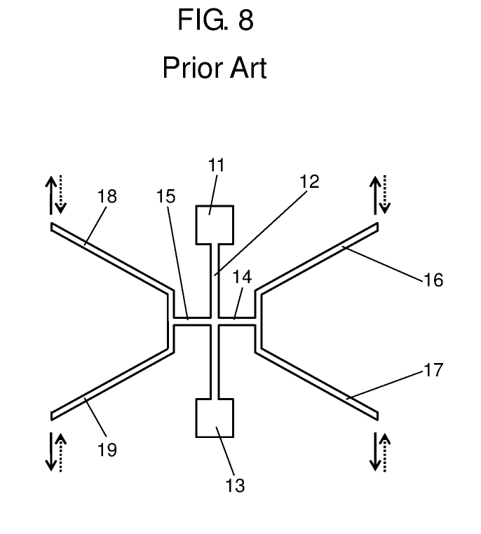

First, referring to the conventional angular velocity sensor element shown in FIG. 8, the area of each of driving body 16, driving body 17, driving body 18 and driving body 19 will be considered.

$$f = \frac{1}{2 π} \frac{{λ}^{2}}{l} + \sqrt{\frac{EI}{ρ A}} \\ l = \sqrt{\frac{1}{2 π} \frac{{λ}^{2}}{f} \sqrt{\frac{EI}{ρ A}}} \\ S = \frac{\frac{1}{2 π} \frac{{λ}^{2}}{f} \sqrt{\frac{EI}{ρ A}}}{2} \qquad 〈 Formula 1 〉$$

In Formula 1, λ denotes a constant, l denotes a length of a driving oscillation body [m], E denotes a longitudinal elastic modulus [Pa], I denotes a moment of inertia of the driving oscillation body [m⁴], p denotes a density of the driving oscillation body [Kg/m³], A denotes a sectional area of the driving oscillation body [m²], and S denotes an area in an extending direction of a driving body [m²].

When specific values are assigned to the variables in Formula 1 as λ=1.87, 1=1.05×10⁻³ [m], E=1.66×10¹¹ [Pa], I=1.55×10⁻²² [m⁴], p=2.33 [Kg/m³], A=5.16×10⁻¹¹, and f=7.35×10⁵ [Hz], an area S in the extending direction of each of driving bodies 16, 17, 18, 19 becomes as S=5.56×10⁻⁷ [m²].

The angular velocity sensor element shown in FIG. 8 can detect angular velocities in biaxial directions by detecting body 12, detecting body 14 and detecting body 15. However, since each of driving body 16, driving body 17, driving body 18 and driving body 19 is extending in the oblique direction of +45 degrees or −45 degrees relative to the X-axis and the Y-axis, the overall length of each driving body is long. Accordingly, although the driving frequency of the conventional angular velocity sensor element shown FIG. 8 is low, there is a problem that the area occupied by the entire angular velocity sensor element is large.

Next, an angular velocity sensor element in accordance with an exemplary embodiment of the present disclosure will be described with reference to the drawings.

### Exemplary Embodiment

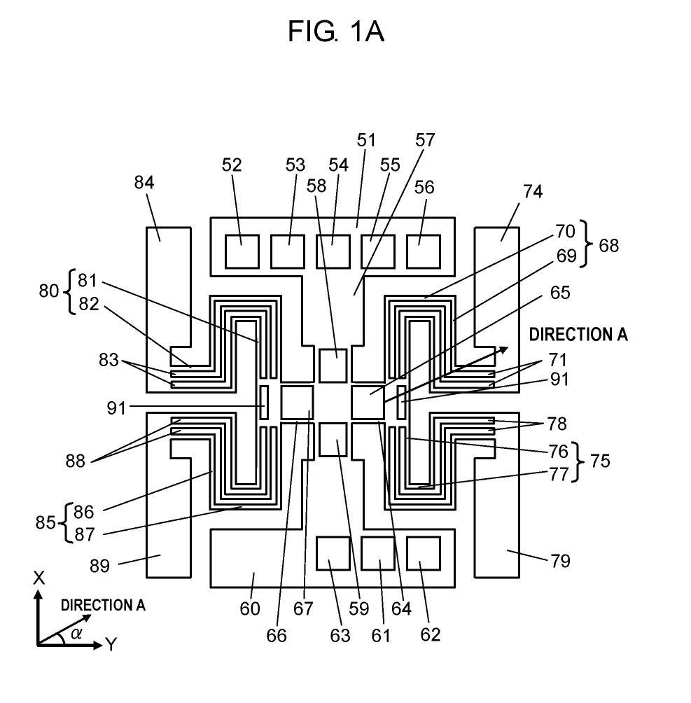

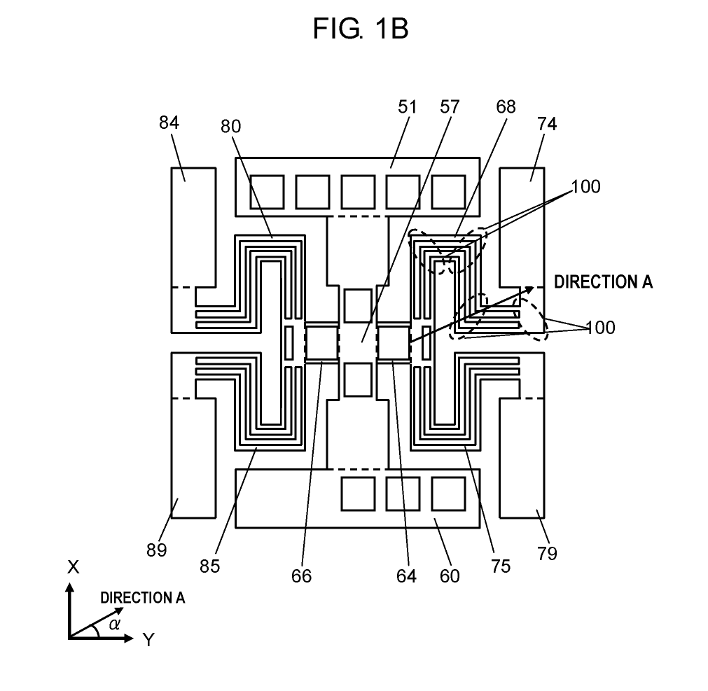

Each of FIG. 1A and FIG. 1B is a top view of an angular velocity sensor element in accordance with the present exemplary embodiment. Although FIG. 1A and FIG. 1B are basically the same figure, boundaries of major components are indicated by broken lines in FIG. 1B. Further, reference marks are added to only the major components in FIG. 1B to avoid complexity of the figure. FIG. 2 is a side sectional view of a driving electrode of the angular velocity sensor element in accordance with the exemplary embodiment.

Description will be made with reference to FIG. 1A and FIG. 1B. Fixed part 51 is made of Si. Driving electrode land 52, driving electrode land 53, detecting electrode land 54, detecting electrode land 55 and ground (GND) electrode land 56 are provided on an upper surface of fixed part 51.

Detecting body 57 is made of Si. One end of detecting body 57 is connected to fixed part 51. Detecting electrode 58 and detecting electrode 59 are provided on an upper surface of detecting body 57.

Formed below detecting electrode 58 are, for example, a common ground (GND) electrode (not shown) made of an alloy thin film composed of Pt and Ti, and a piezoelectric layer (not shown) made of a PZT (lead zirconate titanate) thin film provided on an upper surface of the common GND electrode (not shown). That is, detecting electrode 58 is provided on the upper surface of detecting body 57 through the common GND electrode and the piezoelectric layer.

Fixed part 60 is made of Si. Fixed part 60 is connected to the other end of detecting body 57. Detecting electrode land 61, detecting electrode land 62 and monitoring electrode land 63 are provided on an upper surface of fixed part 60.

Detecting electrode 58 formed on detecting body 57 is electrically connected to detecting electrode land 54 formed on fixed part 51. Detecting electrode 59 formed on detecting body 57 is electrically connected to detecting electrode land 61 formed on fixed part 60.

Detecting body 64 is made of Si. One end of detecting body 64 is connected to approximately a center of detecting body 57. Detecting body 64 is extending from approximately the center of detecting body 57 in a direction (the rightward direction in FIG. 1A) approximately perpendicular to the extending direction of detecting body 57 (the vertical direction in FIG. 1A). Detecting electrode 65 is provided on an upper surface of the detecting body 64. Detecting electrode 65 formed on detecting body 64 is electrically connected to detecting electrode land 55 formed on fixed part 51.

Detecting body 66 is made of Si. One end of detecting body 66 is connected to approximately the center of detecting body 57. Detecting body 66 is extending from approximately the center of detecting body 57 in a direction (the leftward direction in FIG. 1A) approximately perpendicular to the extending direction of detecting body 57 (the vertical direction in FIG. 1A). That is, the extending direction of detecting body 64 from detecting body 57 and the extending direction of detecting body 66 from detecting body 57 are opposite to each other. Detecting body 64 and detecting body 66 are formed integrally on a straight line through detecting body 57. Detecting electrode 67 is provided on an upper surface of detecting body 66.

Detecting electrode 67 formed on detecting body 66 is electrically connected to detecting electrode land 62 formed on fixed part 60.

Driving body 68 is made of Si. Supposing that a direction in which driving body 68 is extending as a whole is defined as a direction from a center of the other end of detecting body 64 to a center of one end of driving body 68, the direction in which driving body 68 is extending as a whole becomes “DIRECTION A” indicated by an arrow in FIG. 1A. In other words, driving body 68 is extending as a whole in a direction between the extending direction of detecting body 57 (hereinafter referred to as the X-axis direction) and the extending direction of detecting body 64 (hereinafter referred to as the Y-axis direction). The angle of DIRECTION A relative to the Y-axis direction is +α degrees.

Driving body 68 is configured to have a folded shape by a combination of driving part 69 extending in the same direction as the extending direction of detecting body 57 and driving part 70 extending in the same direction as the extending direction of detecting body 64. Although plural driving parts 69 and plural driving parts 70 are formed, only a part of the driving parts is indicated by reference marks in FIG. 1A to avoid complexity of the figure.

By a combination of driving part 69 extending in the X-axis direction and driving part 70 extending in the Y-axis direction, driving body 68 includes plural bent portions 100 (shown in FIG. 1B) to form a folded shape.

A pair of driving electrodes 71 is provided on an upper surface of driving body 68.

Here, details of driving electrodes 71 will be described with reference to FIG. 2. FIG. 2 is a side sectional view of a driving electrode of the angular velocity sensor element. Formed below driving electrodes 71 are, for example, common GND electrode 72 made of an alloy thin film composed of Pt and Ti, and piezoelectric layers 73 each made of a PZT thin film provided on an upper surface of common GND electrode 72 as shown in FIG. 2. That is, driving electrodes 71 are provided on the upper surface of driving body 68 through common GND electrode 72 and piezoelectric layers 73.

As described above, an angular velocity sensor element in accordance with the present exemplary embodiment includes: fixed part 51; detecting body 57 connected to fixed part 51, provided with detecting electrode 58, and extending in the X-axis direction; detecting body 64 connected at one end to detecting body 57, extending in the Y-axis direction approximately perpendicular to the X-axis direction, and provided with detecting electrode 65; and driving body 68 connected to the other end of detecting body 64, disposed on a plane on which detecting body 57 and detecting body 64 are disposed, and provided with driving electrode 71. In addition, driving body 68 has a folded shape with two or more bent portions 100. Further, a direction from a connecting portion of detecting body 64 and driving body 68 to an end of driving body 68 is between the X-axis direction and the Y-axis direction in a top view (DIRECTION A).

According to this configuration, driving body 68 is extending in a direction which is different from the extending direction of detecting body 57 (the X-axis direction) and the extending direction of detecting body 64 (the Y-axis direction). Accordingly, it is possible to detect angular velocities in biaxial directions by an oscillation of driving body 68. In addition, since driving body 68 in accordance with the present exemplary embodiment has a folded shape, the driving frequency of the driving body may be low, and it is possible to provide a small-size angular velocity sensor element.

In the angular velocity sensor element in accordance with the present exemplary embodiment, driving body 68 may preferably have driving part 69 extending in the X-axis direction, which is the extending direction of detecting body 57, and driving part 70 extending in the Y-axis direction, which is the extending direction of detecting body 64. Driving electrode 71 is provided on each of driving part 69 and driving part 70.

According to this configuration, it is possible by driving part 69 to drive the angular velocity sensor element to oscillate in a direction (the Y-axis direction) perpendicular to the extending direction of driving part 69 (the X-axis direction). Also, it is possible by driving part 70 to drive the angular velocity sensor element to oscillate in a direction (the X-axis direction) perpendicular to the extending direction of driving part 70 (the Y-axis direction). This makes it possible to improve the output sensitivity of angular velocity detection signals in biaxial directions.

Preferably, the angular velocity sensor element in accordance with the present exemplary embodiment may further include weight part 74. Weight part 74 is connected to an end of driving body 68.

According to this configuration, increase in the mass of the angular velocity sensor element due to weight part 74 increases the Coriolis force generated by the angular velocity. Accordingly, it is possible to improve the sensitivity of angular velocity detection signals in biaxial directions.

### Oscillation Analysis

Next, a result of an oscillation analysis of driving body 68 and weight part 74 will be described.

A result of an oscillation analysis of driving body 68 and weight part 74 by Finite Element Analysis (FEA) will be described.

First, a driving frequency will be calculated in the case of the conventional angular velocity sensor element described with reference to FIG. 8, which has driving body 16 having a linear shape. A required driving frequency f is assumed as f=7.35×10⁵ [Hz]. To achieve the required driving frequency, an element width a=7.34×10⁻⁴ [m] and an element length b=7.34×10⁻⁴ [m] are necessary in the area of driving body 16, so that an area S occupied by driving body 16 shown in FIG. 8 becomes S=5.38×10⁻⁷ [m²].

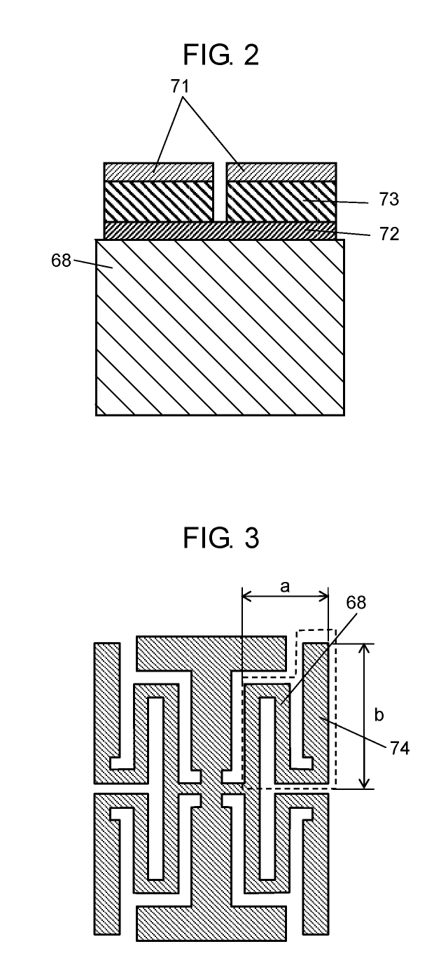

On the other hand, to achieve the required driving frequency in the case of the angular velocity sensor element in accordance with one exemplary embodiment of the present disclosure, as shown in FIG. 3, an element width a=3.18×10⁻⁴ [m] and an element length b=5.76×10⁻⁴ [m] are necessary in the total area of driving body 16 and first weight part 74, so that a total area S occupied by first driving body 68 and first weight part 74 becomes S=1.83×10⁻⁷ [m²]. That is, when the angular velocity sensor element in accordance with the present exemplary embodiment, in which driving body 68 has a folded shape, is compared to the conventional angular velocity sensor element, in which driving body 16 has a linear shape, the angular velocity sensor element in accordance with the present exemplary embodiment can be made so that the area occupied by driving body 68 and weight part 74 is reduced by about 66%.

In other words, in the angular velocity sensor element in accordance with the present exemplary embodiment, driving body 68 is extending in the direction which is different from both the extending direction of detecting body 57 and the extending direction of detecting body 64. Accordingly, it is possible by the oscillation of driving body 68 to perform detection by the angular velocity sensor in bidirectional directions. Also, since driving body 68 has a folded shape, it is possible to lower the driving frequency of driving body 68 and to make the angular velocity sensor element small-sized.

Hereinabove, driving body 68 at the upper right in FIG. 1 of the angular velocity sensor element in accordance with the present exemplary embodiment has been described. Each of driving body 75 shown at the lower right in FIG. 1, driving body 80 shown at the upper left in FIG. 1, and driving part 85 shown at the lower left in FIG. 1 is the same as driving body 68.

Hereinafter, configurations of driving body 75, driving body 80 and driving body 85 will be sequentially described. However, since each of them is the same in configuration as driving body 68, the description on them will be partly omitted.

### Configuration of Driving Body 75

Driving body 75 is made of Si, and is extending as a whole from the other end of detecting body 64 in a direction between the extending direction of detecting body 57 and the extending direction of detecting body 64. In other words, driving body 75 is extending in the direction of −α degrees.

Driving part 76 of driving body 75 is extending in the same direction as the extending direction of detecting body 57. Further, driving part 77 is extending in the same direction as the extending direction of detecting body 64. Driving body 75 is configured in a folded shape formed by combining plural driving parts 69 extending in the X-axis direction and second driving parts 77 extending in the Y-axis direction.

Although plural driving parts 76 and plural driving parts 77 are formed, only a part of them is indicated by reference marks in FIG. 1A and FIG. 1B to avoid complexity of the figures.

A pair of driving electrodes 78 is provided on an upper surface of driving body 75. Driving electrodes 78 are formed to be the same in configuration as driving electrodes 71 which have been described with reference to FIG. 2. Weight part 79 is connected to the other end of driving body 75.

### Configuration of Driving Body 80

Driving body 80 is made of Si, and is extending as a whole from the other end of detecting body 66 in a direction between the extending direction of detecting body 57 and the extending direction of detecting body 66. In other words, driving body 80 is extending in the direction of −α degrees.

Driving part 81 of driving body 80 is extending in the same direction as the extending direction of detecting body 57. Further, driving part 82 is extending in the same direction as the extending direction of detecting body 66. Driving body 80 is configured in a folded shape formed by combining plural driving parts 81 extending in the X-axis direction and plural driving parts 82 extending in the Y-axis direction.

Although plural driving parts 81 and plural driving parts 82 are formed, only a part of them is indicated by reference marks in FIG. 1A and FIG. 1B to avoid complexity of the figures.

A pair of driving electrodes 83 is provided on an upper surface of driving body 80. Driving electrodes 83 are formed to be the same in configuration as driving electrodes 71 which have been described with reference to FIG. 2. Weight part 84 is connected to the other end of driving body 80.

### Configuration of Driving Body 85

Driving body 85 is made of Si, and is extending as a whole from the other end of detecting body 66 in a direction between the extending direction of detecting body 57 and the extending direction of detecting body 66. In other words, driving body 85 is extending in the direction of +α degrees.

Driving part 86 of driving body 85 is extending in the same direction as the extending direction of detecting body 57. Further, driving part 87 is extending in the same direction as the extending direction of detecting body 66. Driving body 85 is configured in a folded shape formed by combining plural driving parts 86 extending in the X-axis direction and plural driving parts 87 extending in the Y-axis direction.

Although plural driving parts 86 and plural driving parts 87 are formed, only a part of them is indicated by reference marks in FIG. 1A and FIG. 1B to avoid complexity of the figures.

A pair of driving electrodes 88 is provided on an upper surface of driving body 85. Driving electrodes 88 are formed to be the same in configuration as driving electrodes 71 which have been described with reference to FIG. 2. Weight part 89 is connected to the other end of driving body 85.

As described above, driving bodies 68, 75, 80, 85 are the same in configuration. Since the angular velocity sensor element in accordance with the present exemplary embodiment has four driving bodies 68, 75, 80, 85, it is possible to largely reduce the volume of the entire angular velocity sensor element compared to the conventional angular velocity sensor element.

Monitoring electrode 91 is provided at each of a portion between driving electrode 71 and driving electrode 78 and a portion between driving electrode 83 and driving electrode 88. Formed below monitoring electrode 91 are, for example, a common GND electrode (not shown) made of an alloy thin film composed of Pt and Ti, and a piezoelectric layer (not shown) made of a PZT thin film provided on an upper surface of the common GND electrode (not shown). That is, monitoring electrode 91 is provided on an upper surface of driving body 68 or driving body 75 through the common GND electrode and the piezoelectric layer.

### Method of Assembling the Angular Velocity Sensor Element

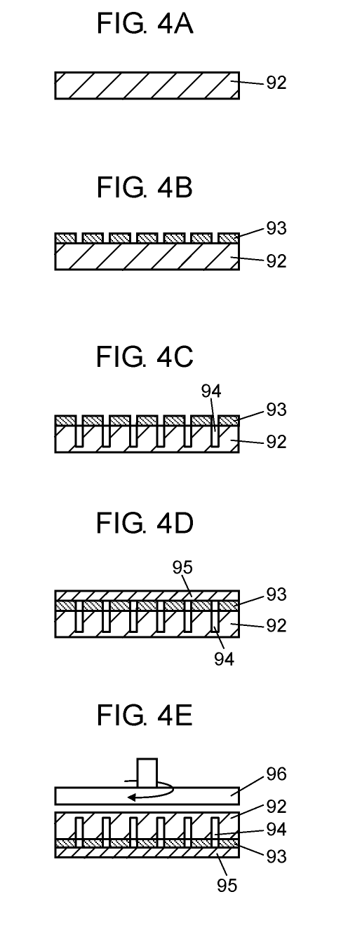

Next, a method of assembling the angular velocity sensor element in accordance with the present exemplary embodiment will be described with reference to FIG. 4A to FIG. 4E. FIG. 4A to FIG. 4E are assembly process diagrams showing an assembly process of the angular velocity sensor element in accordance with the present exemplary embodiment.

First, as shown in FIG. 4A, such wafer 92 is prepared that has an upper surface on which driving electrode land 52, driving electrode land 53, detecting electrode land 54, detecting electrode land 55, GND electrode land 56, detecting electrode land 61, detecting electrode land 62, monitoring electrode land 63 and a wiring pattern have previously been formed. It should be noted that driving electrode land 52, driving electrode land 53, detecting electrode land 54, detecting electrode land 55, GND electrode land 56, detecting electrode land 61, detecting electrode land 62, monitoring electrode land 63 and the wiring pattern are not shown in FIG. 4A to FIG. 4E.

Next, the upper surface of wafer 92 is coated with resist film 93 made, for example, of aluminum, titanium, silicon oxide or silicon nitride by spin coating.

Then, as shown in FIG. 4B, resist film 93 is patterned into a predetermined shape by photolithography.

Next, wafer 92 is set in a dry etching machine (not shown). Then wafer 92 made of Si is etched at the parts other than the parts on which resist film 93 has been formed by introducing a fluorinated gas such, for example, as SF₆ or CF₆ to form grooves 94 as shown in FIG. 4C.

Next, as shown in FIG. 4D, film 95 provided with an adhesive layer (not shown) is adhered to the upper surface of resist film 93. Film 95 has a function of protecting the upper surface of wafer 92 during a step of back grinding in a range of 50 microns to 200 microns. Then, wafer 92 is placed upside down, and film 95 formed on the upper surface of wafer 92 is fixed to a chuck table (not shown).

Next, the back surface of wafer 92 is ground by rotating back grinding wheel 96 as shown in FIG. 4E.

Next, film 95 is irradiated by an ultraviolet (UV) ray to reduce the adhesive strength of film 95, and to cause film 95 to be peeled off from the lower surface of resist film 93. Finally, resist film 93 is removed, and individual angular velocity sensor elements are taken out from wafer 92.

### Operations of the Angular Velocity Sensor Element

Next, operations of the angular velocity sensor element in accordance with the present exemplary embodiment will be described with reference to FIG. 1A and FIG. 5 to FIG. 7.

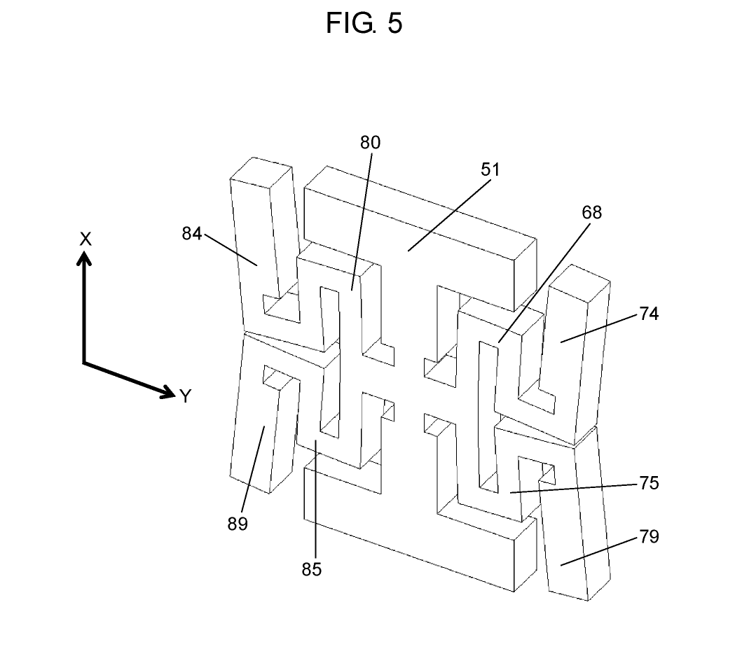

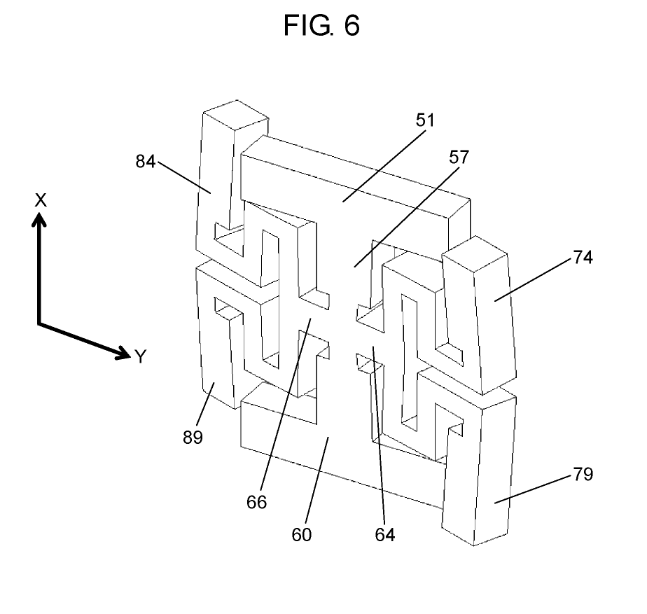

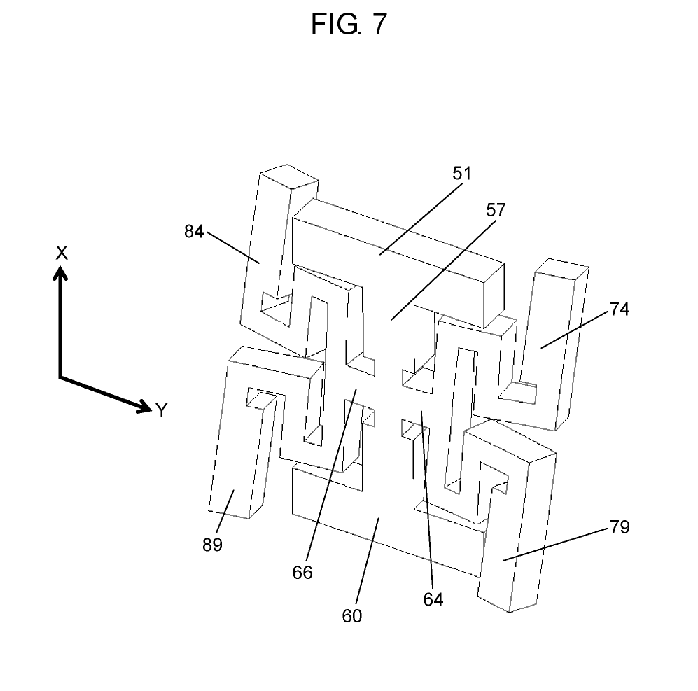

FIG. 5 is a diagram illustrating a state in which the angular velocity sensor element in accordance with the present exemplary embodiment oscillates in the X-axis direction and the Y-axis direction. FIG. 6 is a diagram illustrating an operating state in a case where an angular velocity around the X-axis is generated on the angular velocity sensor element in accordance with the present exemplary embodiment. FIG. 7 is a diagram illustrating an operating state in a case where an angular velocity around the Y-axis is generated on the angular velocity sensor element in accordance with the present exemplary embodiment.

First, an alternating current (AC) voltage is applied to driving electrode land 52 (not shown in FIG. 5 to FIG. 7) and driving electrode land 53 (not shown in FIG. 5 to FIG. 7) on fixed part 51. In a case where the directions of the polarized crystallographic axes of driving electrode 71 provided on driving body 68, driving electrode 78 provided on driving body 75, driving electrode 83 provided on driving body 80 and driving electrode 88 provided on driving body 85 are the same as the direction in which electric charges are flown in driving electrode 88, a tensile stress is generated at each of driving electrodes 71, 78, 83, 88 through the wiring pattern (not shown).

On the other hand, a compressive stress is generated in a case where the direction of the polarized crystallographic axis of driving electrode 88 is opposite to the direction in which electric charges are flown in driving electrode 88.

Accordingly, each of driving body 68, driving body 75, driving body 80 and driving body 85 causes a driving oscillation at velocity V in each of the X-axis direction and the Y-axis direction depending on the phase of the AC voltage. This driving oscillation propagates to each of weight part 74, weight part 79, weight part 84 and weight part 89, so that each of driving body 68, driving body 75, driving body 80 and driving body 85 causes the driving oscillation at velocity V in each of the X-axis direction and the Y-axis direction as shown in FIG. 5.

Next, description will be made on a case in which an angular velocity around the X-axis is generated on the angular velocity sensor element with reference to FIG. 1A and FIG. 6.

As shown in FIG. 6, each of weight part 74, weight part 79, weight part 84 and weight part 89 oscillates around the X-axis due to the Coriolis force. This causes detecting body 57 to be twisted, so that detecting body 64 and detecting body 66 deflect in opposite directions to each other.

Aa a result, an electric charge corresponding to the angular velocity is generated at detecting electrode 65 provided on detecting body 64, and is output to detecting electrode land 55 provided on fixed part 51 through a circuit pattern (not shown).

Also, an electric charge corresponding to the angular velocity is generated at detecting electrode 67 provided on detecting body 66, and is output to detecting electrode land 62 provided on fixed part 60 through a circuit pattern (not shown).

The electric charges output to detecting electrode land 55 and detecting electrode land 62 are converted to voltages, and these electric charges are amplified. Then, a difference between the amplified electric charges is taken to detect the angular velocity around the X-axis.

Next, description will be made on a case in which an angular velocity around the Y-axis is generated on the angular velocity sensor element with reference to FIG. 1A and FIG. 7.

As shown in FIG. 7, each of weight part 74, weight part 79, weight part 84 and weight part 89 oscillates around the Y-axis due to the Coriolis force. This causes detecting body 64 and detecting body 66 to be twisted, so that detecting body 57 deforms such that the part on the side of fixed part 51 and the part on the side of fixed part 60 deflect in opposite directions to each other.

Aa a result, an electric charge corresponding to the angular velocity is generated at detecting electrode 58 provided on detecting body 57, and is output to detecting electrode land 54 provided on fixed part 51 through a circuit pattern (not shown).

Also, an electric charge corresponding to the angular velocity is generated at detecting electrode 59 provided on detecting body 57, and is output to detecting electrode land 61 provided on fixed part 60 through a circuit pattern (not shown).

The electric charges output to detecting electrode land 54 and detecting electrode land 61 are converted to voltages, and these electric charges are amplified. Then, a difference between the amplified electric charges is taken to detect the angular velocity around the Y-axis.

Particularly, the angular velocity sensor element in accordance with the present exemplary embodiment is configured such that driving body 68 is configured by driving part 69 approximately parallel to detecting body 57 and driving part 70 approximately parallel to detecting body 64, and that driving electrodes 71 are provided on both of driving part 69 and driving part 70. According to this configuration, driving electrodes 71 provided on both of driving part 69 and driving part 70 allow driving part 69 to cause a driving oscillation in a direction perpendicular to the extending direction of driving part 69, and allow driving part 70 to cause a driving oscillation in a direction perpendicular to the extending direction of driving part 70. Accordingly, it is possible to improve the sensitivity of the angular velocity detection signals in biaxial directions.

Although weights 74, 79, 84, 89 are formed in the angular velocity sensor element in accordance with the present exemplary embodiment, the weights may not necessarily be formed.

Although driving body 68, for example, is configured by combining driving part 69 extending in the X-axis direction and driving part 70 extending in the Y-axis direction, driving body 68 may be configured by combining driving parts that are extending in oblique directions. Each of the driving parts configuring driving body 68 may not necessarily be extending only in the X-axis direction or the Y-axis direction. Driving body 68 may as a whole be extending in a direction between the X-axis direction and the Y-axis direction. Much the same is true on other driving bodies 75, 80, 85.

Although driving body 68 in accordance with the present exemplary embodiment has four bent portions 100, driving body 68 may not necessarily have four bent portions 100. Driving body 68 may have at least two bent portions 100 to form a folded shape. Much the same is true on other driving bodies 75, 80, 85.

### INDUSTRIAL APPLICABILITY

According to the present disclosure, it is possible to provide an angular velocity sensor element that is driven at a low driving frequency of the driving body and small in size. Particularly, the present disclosure is useful as an angular velocity sensor element used for angular velocity sensors which are employed in various kinds of electronic device.

### REFERENCE MARKS IN THE DRAWINGS

51, 60 fixed part
52 driving electrode land
53 electrode land
54, 55, 61, 62 detecting electrode land
56 GND electrode land
57, 64, 66 detecting body
58, 59, 65, 67 detecting electrode
63 monitoring electrode land
68, 75, 80, 85 driving body
69, 76, 81, 86 driving part
70, 77, 82, 87 driving part
71, 78, 83, 88 driving electrode
74, 79, 84, 89 weight part
91 monitoring electrode
92 wafer
93 resist film
94 groove
95 film
96 back grinding wheel
100 bent portion

1. An angular velocity sensor element comprising:
a fixed part;
a first detecting body connected to the fixed part and extending in a first direction, the first detecting body being provided with a first detecting electrode;
a second detecting body connected at one end to the first detecting body and extending in a second direction approximately perpendicular to the first direction, the second detecting body being provided with a second detecting electrode; and
a driving body connected to the other end of the second detecting body and disposed on a plane on which the first detecting body and the second detecting body are disposed, the driving body being provided with a driving electrode,
wherein
the driving body has a folded shape with two or more bent portions, and
a direction from a connecting portion of the second detecting body and the driving body to an end of the driving body is between the first direction and the second direction in a top view.

2. The angular velocity sensor element according to claim 1, wherein the driving body has:
a first driving part extending in the first direction in which the first detecting body extends; and
a second driving part extending in the second direction in which the second detecting body extends, and
the driving electrode is provided on each of the first driving part and the second driving part.

3. The angular velocity sensor element according to claim 1, further comprising a weight part,
wherein the weight part is connected to the end of the driving body.
